(19) United States
(12) Patent Application Publication
(10) Pub. No.: US 2009/0243119 A1
(43) Pub. Date: Oct. 1, 2009

(54) Semiconductor integrated circuit

(75) Inventor: Toshiaki Terayama, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/382,814

(22) Filed: Mar. 24, 2009

(30) Foreign Application Priority Data
Mar. 28, 2008 (JP) 2008-087243

(51) Int. Cl. H01L 23/498

(52) U.S. Cl. 257/774; 257/E23.062

(57) ABSTRACT

Power wiring comprises a first-layer power wiring cluster in which VDD wiring trace and VSS wiring trace of different potentials at single trace width are arranged alternatingly; a second-layer power wiring cluster, disposed in a layer overlying the first-layer power wiring cluster, in which a VDD wiring trace and a VSS wiring trace of different potentials at single trace width are arranged alternatingly; and vias, placed in areas where the first-layer power wiring cluster and second-layer power wiring clusters intersect three-dimensionally, for electrically connecting wiring traces of the same potential in the first-layer power wiring cluster and wiring traces of the same potential in the second-layer power wiring cluster. A signal-wiring formation area is provided between mutually adjacent first-layer power wiring clusters and between mutually adjacent second-layer power wiring clusters. Design rule violation regarding via density is avoided without decline in integration or an increase in chip area.

### REFERENCE TO RELATED APPLICATION

This application is based upon and claims the benefit of the priority of Japanese patent application No. 2008-087243, filed on Mar. 28, 2008, the disclosure of which is incorporated herein in its entirety by reference thereto.

### TECHNICAL FIELD

This invention relates to a semiconductor integrated circuit and, more particularly, to a semiconductor integrated circuit having clustered wiring traces (termed as “wiring-trace cluster” herein) in which wiring traces of a single trace width are placed at prescribed intervals.

### BACKGROUND

The wiring traces in a semiconductor integrated circuit are routed according to a prescribed design rule. In cases where the structure is such that the wiring traces are placed in multiple layers, the wiring layers are electrically connected by way of vias. In order to reduce the effects of voltage drop in such a multiple-layer wiring structure, generally the power wiring and ground wiring employ wiring traces having a trace width that is large in comparison with the signal wiring, or uses wiring-trace cluster in which wiring traces having a single trace width the same as that of the signal wiring are arranged in parallel at prescribed intervals. In cases where the power wiring includes power wiring (VDD wires and VSS wires) having potentials of two different levels, these wiring traces are laid out alternatingly (e.g., see Patent Document 1, FIG. 3).

[Patent Document 1]

JP Patent Kokai Publication No. JP2005-259913A

[Patent Document 2]

JP Patent Kokai Publication No. JP2003-141200A

### SUMMARY

The entire disclosures of the above mentioned Patent Documents are incorporated herein by reference hereto. The following analyses are given by the present invention.

In the case of thick-trace wiring shown in FIG. 3A, the trace spacing is large and hence there is no particular problem with regard to violation of the design rule concerning the density of vias 150, 160 between wiring layers. In the case of a wiring-trace cluster formulation shown in FIG. 3B, however, trace spacing in the wiring-trace cluster 210, 220, 230, 240 is small, which tends to violate the design rule concerning the density of vias 251, 261 between wiring layers. In order to avoid violation of the design rule, it is required to enlarge the width of wiring traces 211, 221, 231, 241 and the spacing thereof. However, doing so lowers the degree of integration and increases chip area.

A layout design method for semiconductor integrated circuits has been disclosed (see Patent Document 2) as a technique for suppressing area-related loss ascribable to such broadening of trace spacing of wiring subdivided as in the wiring-trace cluster formulation of FIG. 3B. Specifically, the method includes dividing wiring traces which are in a mutually intersecting positional relationship into regions of trace intersection and regions other than these regions of trace intersection, and inserting slits in the respective regions. In order to abide by the design rule in this technique, the area of the trace intersections must be enlarged. If the area of intersections is enlarged, regions for forming the signal wiring traces between the wiring-trace clusters diminish in size and there is a decline in the degree of freedom regarding the routing of the signal wiring. If an attempt is made to assure the degree of freedom of signal wiring routing, there is the danger of a decline in the degree of integration and of an increase in chip area.

Thus there is a need in the art to provide a semiconductor integrated circuit that can avoid violation of the design rule relating to the via density without lowering in the integration or increase in the chip area even when the clustered wiring traces are used.

In a first aspect of the present invention, there is provided a semiconductor integrated circuit has a power wiring structure in which, in areas where clusters of wiring traces (i.e. wiring-trace clusters) intersect each other three-dimensionally, the wiring-trace clusters each having wiring traces of different potentials at a single trace width arranged alternatingly, wiring traces of the same potential in each wiring-trace cluster are electrically connected each other by vias. A signal-wiring formation area for forming a signal wiring (s) is provided between mutually adjacent ones of the wiring-trace clusters placed in the same layer.

The meritorious effects of the present invention are summarized as follows.

Clusters of wiring traces (wiring-trace clusters) in which wiring traces of different potentials and a single trace width are arranged alternatingly are used as power wiring. As a result, locations where wiring traces of the same potential intersect occur every other wiring trace. Consequently, even though clustered wiring traces are used, violation of design rule regarding the density of vias can be avoided without causing a decline in degree of integration or an increase in chip area.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIGS. 1A and 1B schematically illustrate a wiring structure of a semiconductor integrated circuit according to an exemplary embodiment of the present invention, in which FIG. 1A is a partial plan view and FIG. 1B is an enlarged plan view of the area of a three-dimensional intersection;

FIGS. 2A to 2D schematically illustrate wiring structures of the semiconductor integrated circuit according to the exemplary embodiment of the present invention, in which FIGS. 2A, 2B, 2C and 2D are sectional views taken along lines W-W′, X-X′, Y-Y′ and Z-Z′, respectively, of FIG. 1B and

FIGS. 3A and 3B schematically illustrate wiring structures of a semiconductor integrated circuit according to comparative examples of related arts, in which FIG. 3A is a partial plan view of thick wiring and FIG. 3B a partial plan view of clustered wiring.

### PREFERRED MODES

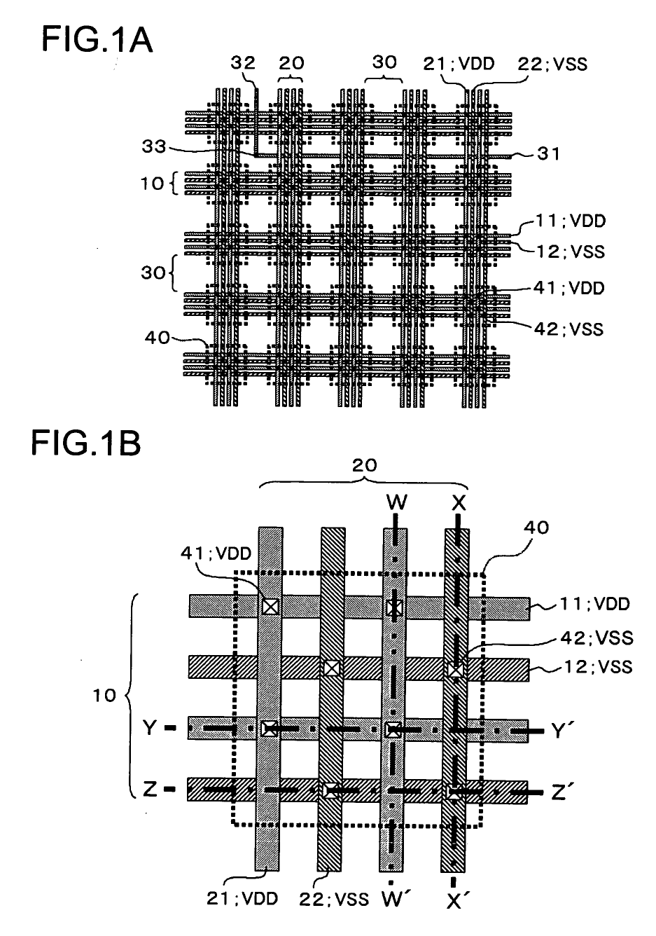

In the following preferred modes are disclosed. In a semiconductor integrated circuit according to the present mode, wiring-trace clusters 10, 20 (FIGS. 1A, 1B) having wiring traces 11, 12, 21, 22 (FIGS. 1A, 1B) of different potentials and a single trace width arranged alternatingly intersect each other three-dimensionally in areas 40 (FIGS. 1A, 1B). The semiconductor integrated circuit has a power wiring structure in which wiring traces of the same potential (11 and 21, 12 and 22 in FIGS. 1A, 1B) in each wiring-trace cluster 10, 20 are electrically connected by vias 41, 42 (FIGS. 1A, 1B). A signal-wiring formation area 30 (FIGS. 1A, 1B) for forming at least one signal wiring trace 31, 32 (FIGS. 1A, 1B) is provided between mutually adjacent ones of the wiring-trace clusters (between clusters 10 and 10 and between clusters 20 and 20 in FIGS. 1A, 1B) placed in the same layer.

A trace width of the wiring traces in the wiring-trace clusters may be the same as that of the signal wiring(s).

A trace pitch of the wiring traces in the wiring-trace clusters may be the same as that of the signal wirings.

The power wiring structure may include a plurality of first wiring-trace clusters in which wiring traces of different potentials at a single trace width are arranged alternatingly; a plurality of second wiring-trace clusters, placed in a layer overlying the first wiring trace clusters, in which wiring traces of different potentials at a single trace width are arranged alternatingly; and a plurality of vias, which are arranged in areas where the first wiring-trace clusters and the second wiring-trace clusters intersect three-dimensionally, electrically connecting wiring traces of the same potential in the first wiring-trace clusters to wiring traces in the second wiring-trace clusters; the signal-wiring formation area being provided between mutually adjacent first wiring-trace clusters and between mutually adjacent second wiring-trace clusters.

In the first wiring-trace clusters, first and second wiring traces of different potentials at a single trace width may be arranged alternatingly; in the second wiring-trace clusters, first and second wiring traces of different potentials at a single trace width may be arranged alternatingly; and the vias may include: a plurality of first vias electrically connecting the first wiring traces of the first wiring-trace clusters to the first wiring traces of the second wiring-trace clusters; and a plurality of second vias electrically connecting the second wiring traces of the first wiring-trace clusters to the second wiring traces of the second wiring-trace clusters.

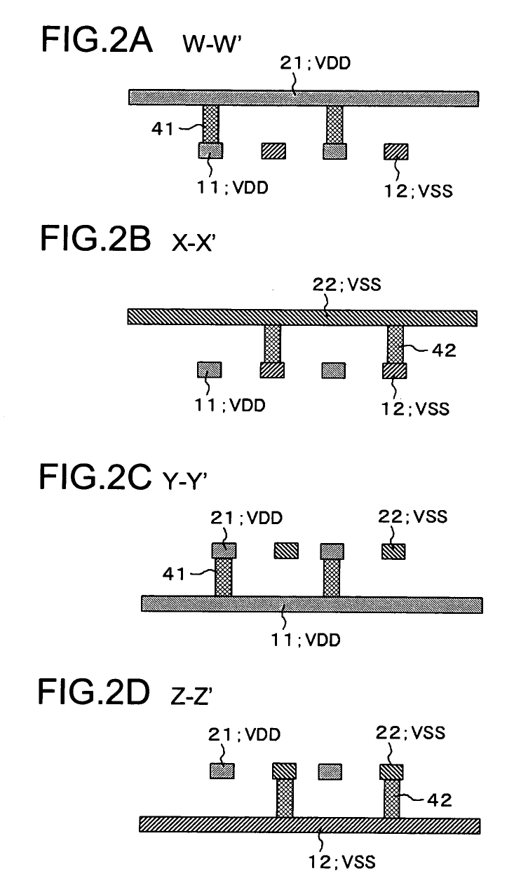

A semiconductor integrated circuit according to an exemplary embodiment will now be described with reference to the drawings. FIGS. 1A and 1B schematically illustrate the wiring structure of a semiconductor integrated circuit according to the exemplary embodiment, in which FIG. 1A is a partial plan view and FIG. 1B is an enlarged plan view of the area of a three-dimensional intersection. FIGS. 2A to 2D schematically illustrate the wiring structure of the semiconductor integrated circuit according to the exemplary embodiment, in which FIGS. 2A, 2B, 2C and 2D are sectional views taken along lines W-W′, X-X′, Y-Y′ and Z-Z′, respectively, of FIG. 1B. It should be noted that insulating layers are not shown in FIGS. 1A, 1B and FIGS. 2A to 2D.

With reference to FIGS. 1A, 1B, the semiconductor integrated circuit has multiple wiring layers in which insulating layers and wiring layers are built up alternatingly on elements formed on a semiconductor substrate, the wiring layers being connected by way of vias. The multiple wiring layers have a power wiring structure. The power wiring structure includes wiring-trace clusters 10 (20) in each of which wiring traces 11, 12 (21, 22) of different potentials and a single trace width are arranged alternatingly. In a three-dimensional intersection area 40 where the wiring-trace clusters 10, 20 intersect each other three-dimensionally, the wiring traces 11 and 21 (12 and 22) of the same potential are electrically connected by a via 41 (42). A signal-wiring formation area 30 for forming signal wiring traces 31 to 33 is provided between mutually adjacent wiring-trace clusters 10 (20) disposed in the same layer.

The first-layer power wiring-trace cluster 10 is a cluster of power wiring traces in which VDD wiring traces 11 and VSS wiring traces 12 of different potentials (levels) and a single trace width are arranged in parallel alternatingly at prescribed intervals. By clustering the VDD wiring traces 11 and the VSS wiring traces 12, the effects of voltage drop can be reduced. Signal wiring is not routed in the spaces between the VDD wiring traces 11 and VSS wiring traces 12 in the first-layer power wiring-trace cluster 10 also in the sense that these wiring traces are gathered together as power wiring traces.

The second-layer power wiring-trace cluster 20 is disposed in a second layer overlying the first layer and is a cluster of power wiring traces in which VDD wiring traces 21 and VSS wiring traces 22 of different potentials and a single trace width are arranged in parallel alternatingly. By clustering the VDD wiring traces 21 and the VSS wiring traces 22, the effects of voltage drop can be reduced. Signal wiring is not routed in the spaces between the VDD wiring traces 21 and VSS wiring traces 22 in the second-layer power wiring-trace cluster 20 also in the sense that these wiring traces are gathered together as power wiring traces.

The signal-wiring formation area 30 is an area for forming signal wiring traces 31 to 33 between mutually adjacent first-layer power wiring-trace clusters 10 and between mutually adjacent second-layer power wiring-trace clusters 20. The first-layer signal wiring trace 31 is placed in the same layer as that of the first-layer power wiring-trace clusters 10 and is disposed at a prescribed position between mutually adjacent first-layer power wiring-trace clusters 10. The second-layer signal wiring trace 32 is placed in the same layer as that of the second-layer power wiring-trace clusters 20 and is disposed at a prescribed position between mutually adjacent second-layer power wiring-trace clusters 20. Signal via 33 electrically connecting the first-layer signal wiring trace 31 and second-layer signal wiring trace 32 is placed in an area where the first-layer signal wiring trace 31 and second-layer signal wiring trace 32 intersect three-dimensionally.

Three-dimensional intersection area 40 is an area where the first-layer power wiring-trace cluster 10 and second-layer power wiring-trace cluster 20 intersect three-dimensionally. A VDD via 41 and a VSS via 42 are provided between the first-layer power wiring-trace cluster 10 and second-layer power wiring-trace cluster 20. The VDD via 41 is a via that electrically connects the VDD wiring trace 11 of the first-layer power wiring-trace cluster 10 and the VDD wiring trace 21 of the second-layer power wiring-trace cluster 20. The via 42 is a via that electrically connects the VSS wiring trace 12 of the first-layer power wiring-trace cluster 10 and the VSS wiring trace 22 of the second-layer power wiring-trace cluster 20. It should be noted that the three-dimensional intersection area 40 is such that no via is placed between the VDD wiring trace 11 of the first-layer power wiring-trace cluster 10 and the VSS wiring trace 22 of the second-layer power wiring-trace cluster 20, and between the VSS wiring trace 12 of the first-layer power wiring-trace cluster 10 and the VDD wiring trace 21 of the second-layer power wiring-trace cluster 20. This makes it possible to avoid violating the design rule regarding via density.

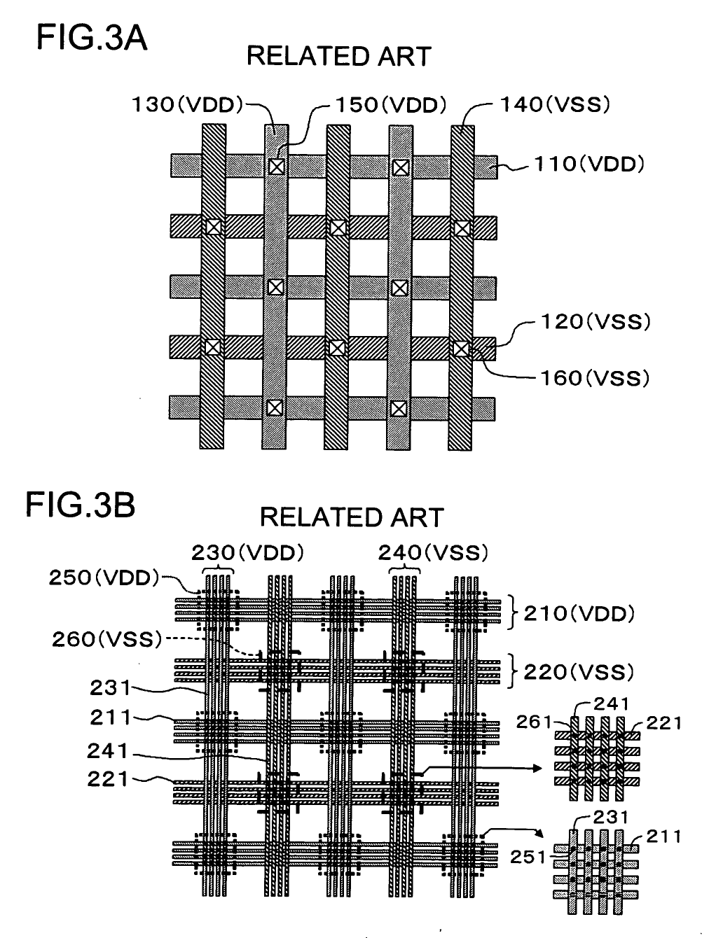

In accordance with the first exemplary embodiment, the wiring-trace clusters 10 (20) in each of which wiring traces 11, 12 (21, 22) of different potentials and a single trace width are arranged alternatingly are used as power wiring, thereby making it possible to avoid violating the design rule regarding via density. The reason for this is as follows: When the power wiring is constituted solely by wiring clusters in which a plurality of wiring traces of the same potential are arranged in parallel, vias are provided at all locations where the wiring traces intersect (see FIG. 3B). However, if the arrangement of the illustrated exemplary embodiment is adopted, locations where wiring traces of the same potential intersect occur every other wiring trace. This makes it possible to avoid violating the design rule. Further, in the conventional clustered wiring trace arrangement (see FIG. 3B), intersecting wiring-trace clusters are connected by vias every other cluster. As a consequence, via spacing equivalent to a pitch of two clusters exists. However, by adopting the arrangement of the illustrated exemplary embodiment, wiring traces of the same potential are via-connected at every area of three-dimensional intersection so that a via spacing equivalent to a maximum pitch of one cluster suffices. This makes it possible to strengthen the power supply (stabilize the power-supply potential).

As many apparently widely different exemplary embodiments of the present invention can be made without departing from the spirit and scope thereof, it is to be understood that the invention is not limited to the specific exemplary embodiments thereof except as defined in the appended claims.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor integrated circuit comprising:
a power wiring structure in which wiring traces of the same potential in each wiring-trace cluster are electrically connected each other by vias in areas where wiring-trace clusters intersect each other three-dimensionally, the wiring-trace clusters each having alternatingly arranged wiring traces of different potentials at a single trace width; and
a signal-wiring formation area for forming a signal wiring(s) between mutually adjacent ones of the wiring-trace clusters placed in the same layer.

2. The semiconductor integrated circuit according to claim 1, wherein a trace width of the wiring traces in said wiring-trace clusters is the same as that of the signal wiring(s).

3. The semiconductor integrated circuit according to claim 1, wherein a trace pitch of the wiring traces in said wiring-trace clusters is the same as that of the signal wirings.

4. The semiconductor integrated circuit according to claim 1, wherein said power wiring structure includes:
a plurality of first wiring-trace clusters in which wiring traces of different potentials at a single trace width are arranged alternatingly;
a plurality of second wiring-trace clusters, placed in a layer overlying said first wiring trace clusters, in which wiring traces of different potentials at a single trace width are arranged alternatingly; and
a plurality of vias, which are arranged in areas where said first wiring-trace clusters and said second wiring-trace clusters intersect three-dimensionally, electrically connecting wiring traces of the same potential in said first wiring-trace clusters to wiring traces in said second wiring-trace clusters;
said signal-wiring formation area being provided between mutually adjacent first wiring-trace clusters and between mutually adjacent second wiring-trace clusters.

5. The semiconductor integrated circuit according to claim 4, wherein
in said first wiring-trace clusters, first and second wiring traces of different potentials at a single trace width are arranged alternatingly;
in said second wiring-trace clusters, first and second wiring traces of different potentials at a single trace width are arranged alternatingly; and
said vias include:
a plurality of first vias electrically connecting the first wiring traces of said first wiring-trace clusters to the first wiring traces of said second wiring-trace clusters; and
a plurality of second vias electrically connecting the second wiring traces of said first wiring-trace clusters to the second wiring traces of said second wiring-trace clusters.
